(19) United States
(12) Patent Application Publication
(10) Pub. No.: US 2024/0429054 A1
(43) Pub. Date: Dec. 26, 2024

(54) METHOD FOR FORMING PATTERNS WITH DIFFERENT CRITICAL DIMENSIONS

(71) Applicant: COMMISSARIAT À L’ENERGIE ATOMIQUE ET AUX ENERGIES ALTERNATIVES, PARIS (FR)

(72) Inventors: Patricia PIMENTA BARROS, GRENOBLE CEDEX 9 (FR); Claire FENOUILLET-BERANGER, GRENOBLE CEDEX 9 (FR)

(21) Appl. No.: 18/748,271

(22) Filed: Jun. 20, 2024

(30) Foreign Application Priority Data
Jun. 20, 2023 (FR) 2306337

(51) Int. Cl. H01L 21/033; H01L 21/311

(52) U.S. Cl. CPC H01L 21/0337; H01L 21/31144

(57) ABSTRACT

A method for forming a first and a second group of patterns on a surface of a substrate, the first group of patterns being located in a first region of the surface of the substrate and the second group of patterns being located in a second region of the surface of the substrate, the method including forming a first sacrificial pattern and a second sacrificial pattern on the substrate, the first sacrificial pattern being located in the first region and having a first critical dimension, the second sacrificial pattern being located in the second region and having a second critical dimension strictly smaller than the first critical dimension; forming first spacers in the first region, on flanks of the first sacrificial pattern, and in the second region, on flanks of the second sacrificial pattern; forming a second spacer on a flank of each first spacer located in the second region.

### CROSS-REFERENCE TO RELATED APPLICATIONS

This application claims priority to French Patent Application No. 2306337, filed Jun. 20, 2023, the entire content of which is incorporated herein by reference in its entirety.

### FIELD

The technical field of the invention is that of advanced lithography techniques for the microelectronics industry. The present invention more particularly relates to a method for forming patterns on a substrate, especially comprising forming spacers on the flanks of sacrificial patterns and removing the sacrificial patterns.

### BACKGROUND

Self-Aligned Double Patterning (SADP) is an advanced lithography technique that doubles density of patterns achieved using conventional photolithography equipment, such as a 193 nm immersion scanner.

This technique comprises five steps, illustrated in FIG. 1:
a) forming, on a substrate 10, sacrificial patterns 20 called “mandrels” or “guides”, typically by photolithography and etching a sacrificial layer;
b) conformally depositing a structural layer 30 made of a material called “spacer” on the substrate 10 and the sacrificial patterns 20;
c) anisotropically etching the structural layer 30, so as to keep only its vertical parts, disposed on the flanks of the sacrificial patterns 20 and forming spacers 40;
d) removing the sacrificial patterns 20, selectively with respect to the spacers 40;
e) transferring the spacers 40 to a superficial portion of the substrate 10 (typically comprised of a hard mask layer).

A drawback of the SADP technique is that all the spacers 40 formed on the substrate 10 have a same critical dimension CD, defined by the thickness of the structural layer 30. However, the manufacture of an integrated circuit requires the formation of patterns with different critical dimensions.

Document [“Analysis of process characteristics of self-aligned multiple patterning”, Y. Chen et al, Microelectronic engineering, vol. 98, pp. 184-188, 2012] describes a method for simultaneously forming a first group of patterns having a first critical dimension and a second group of patterns having a second critical dimension different from the first one.

FIG. 2 illustrates the main steps of this method:
a) forming first mandrels 20a on a first region 10a of a substrate 10 and second mandrels 20b on a second region 10b of the substrate 10, the first mandrels 20a having a critical dimension CD₁ greater than the critical dimension CD₂ of the second mandrels 20b;
b) forming first spacers 41, referred to as sacrificial spacers, on the flanks of the first and second mandrels 20a-20b;
c) forming second spacers 42, referred to as structural spacers, on the flanks of the sacrificial spacers 41;
d) removing the sacrificial spacers 41 selectively with respect to the mandrels 20a-20b and the structural spacers 42; and
e) transferring the mandrels 20a-20b and structural spacers 42 into a superficial portion of the substrate 10.

The density of the patterns initially formed in the second region 10b (the second mandrels 20b) is tripled by virtue of the double formation of spacers (steps b) and c)). The second region 10b is therefore referred to as the “SATP” (Self-Aligned Triple Patterning) region. On the other hand, in the first region 10a, the structural spacers 42 between two first mandrels 20a are merged so as to achieve doubling of the pattern density (so-called “SADP” region), rather than tripling.

This method therefore makes it possible to simultaneously form patterns of different critical dimensions, depending on the regions of the substrate. However, it does not make it possible to obtain a pitch between patterns of the first region 10a (comprised of the first mandrels 20a and the structural spacers 42) that is identical to the pitch between patterns of the second region 10b (comprised of the second mandrels 20b and the structural spacers 42). Furthermore, the patterns of the first region 10a are not regular in terms of critical dimension, as the first pattern and the last pattern are comprised of a single structural spacer 42. Finally, merging of the structural spacers 42 is restrictive, as it requires perfect control of the space between the first two mandrels 20a.

### SUMMARY

There is therefore a need to provide a method for forming a first group of patterns and a second group of patterns, the patterns of the first group having a different critical dimension from those of the second group, but the same pitch.

According to an aspect of the invention, this need tends to be satisfied by providing a method for forming a first group of patterns and a second group of patterns on a surface of a substrate, the first group of patterns being located in a first region of the surface of the substrate and the second group of patterns being located in a second region of the surface of the substrate, the method comprising the following steps of:
forming a first sacrificial pattern and a second sacrificial pattern on the substrate, the first sacrificial pattern being located in the first region and having a first critical dimension, the second sacrificial pattern being located in the second region and having a second critical dimension strictly smaller than the first critical dimension;
forming first spacers in the first region, on flanks of the first sacrificial pattern, and in the second region, on flanks of the second sacrificial pattern, forming the first spacers comprising the following sub-steps of:
   conformally depositing a first structural layer in the first and second regions;
   anisotropically etching the first structural layer;
forming a second spacer on a flank of each first spacer located in the second region, forming the second spacers comprising the following sub-steps of:
   conformally depositing a second structural layer in the first and second regions, the second structural layer having a thickness equal to the difference between the first critical dimension and the second critical dimension;
   anisotropically etching the second structural layer; and
   removing the second structural layer in the first region;
removing the first and second sacrificial patterns selectively with respect to the first and second spacers.

Thus the patterns of the second group have a larger critical dimension than the patterns of the first group, due to the formation of the second spacers against the first spacers in the second region. The critical dimension difference is generated by a conformal deposition sub-step (for the second structural layer), which is easy to implement and can be controlled (to within one nm) by virtue of Atomic Layer Deposition (ALD) techniques. The pitch is kept between the patterns of the first group and those of the second group, by virtue of the fact that the critical dimension difference is found between the first and second sacrificial patterns initially formed.

In an embodiment, the first sacrificial pattern separates two first cavities having a third critical dimension, the second sacrificial pattern separates two second cavities having a fourth critical dimension and the first and second spacers are formed on side walls of the first and second cavities.

Beneficially, the third critical dimension and the fourth critical dimension satisfy the following relationships:

$$C {D}_{3} = C {D}_{1} + 2 \times {e}_{1}$$

$$C {D}_{4} = C {D}_{2} + 2 \times {e}_{1} + 2 \times {e}_{2}$$

where CD₁ is the first critical dimension, e₁ is the thickness of the first structural layer, CD₂ is the second critical dimension and e₂ is the thickness of the second structural layer.

In first and second embodiments of the method, conformally depositing the second structural layer is performed after anisotropically etching the first structural layer.

In a third embodiment, conformally depositing the second structural layer is subsequent to conformally depositing the first structural layer and anisotropically etching the first structural layer is subsequent to anisotropically etching the second structural layer.

Further to the characteristics just discussed in the previous paragraphs, the method according to one or more embodiments of the invention may have one or more of the following additional characteristics, considered individually or according to any technically possible combinations:
removing the second structural layer in the first region is accomplished after anisotropically etching the second structural layer;
removing the second structural layer in the first region is accomplished before anisotropically etching the second structural layer;
removing the first and second sacrificial patterns is accomplished after removing the second structural layer in the first region;
removing the first and second sacrificial patterns is accomplished between anisotropically etching the second structural layer and removing the second structural layer in the first region;
removing the second structural layer in the first region comprises forming an etch mask on the second structural layer in the second region, etching the second structural layer through the etch mask selectively with respect to the first sacrificial layer, and removing the etch mask;
the difference between the first critical dimension and the second critical dimension is greater than or equal to 4 nm, such as between 4 nm and 70 nm.

### BRIEF DESCRIPTION OF THE FIGURES

Further characteristics and benefits of the invention will become clearer from the description thereof given below, by way of indicating and in no means limiting purposes, with reference to the appended figures, among which:

FIG. 1 represents steps of a first method for forming patterns, referred to as “SADP”;

FIG. 2 represents steps of a second method for forming patterns according to prior art;

FIG. 3A to 3I represent, in a schematic cross-sectional view, a first embodiment of the method for forming patterns according to the invention;

FIG. 4A to 4I represent, in a schematic cross-sectional view, a second embodiment of the method for forming patterns according to the invention; and

FIG. 5A to 5H represent, in a schematic cross-sectional view, a third embodiment of the method for forming patterns according to the invention; and

FIG. 6A to 6D represent, in a schematic cross-sectional view, a fourth embodiment of the method for forming patterns according to the invention.

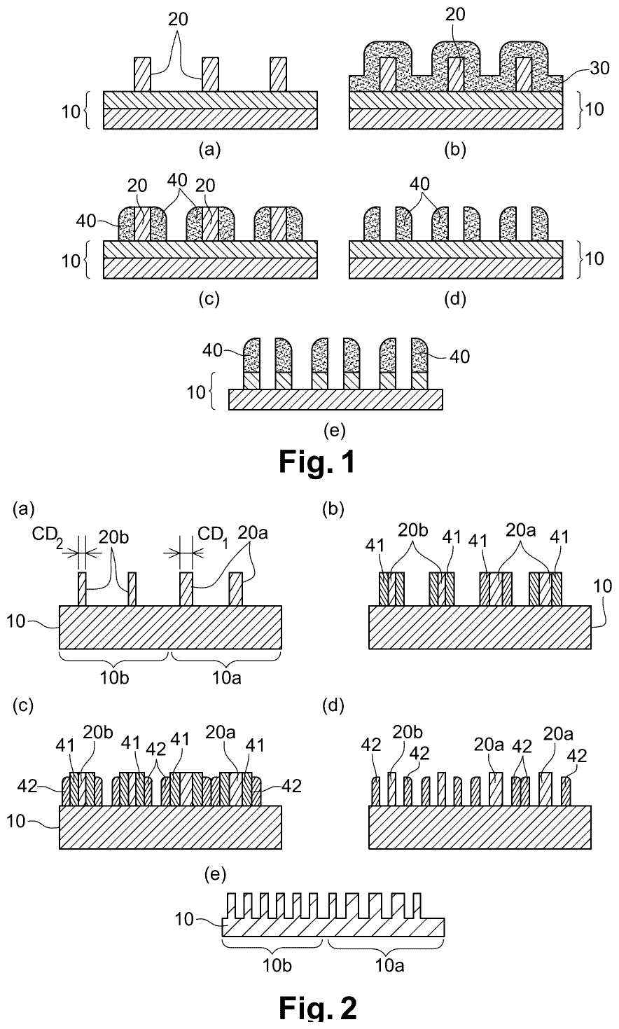

For greater clarity, identical or similar elements are marked by identical reference signs throughout the figures.

### DETAILED DESCRIPTION

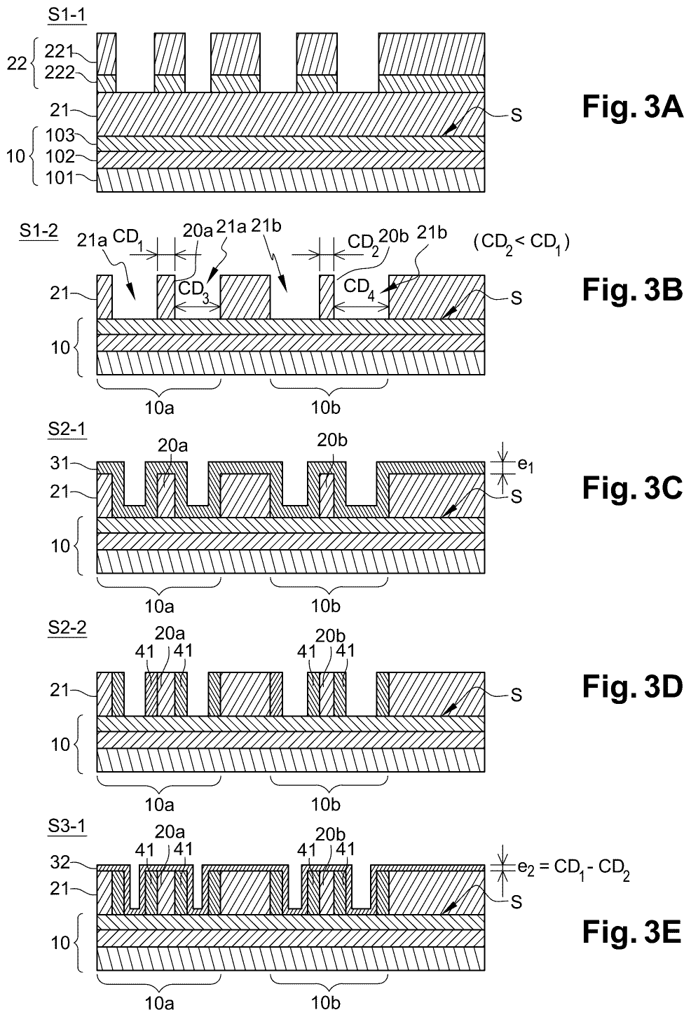

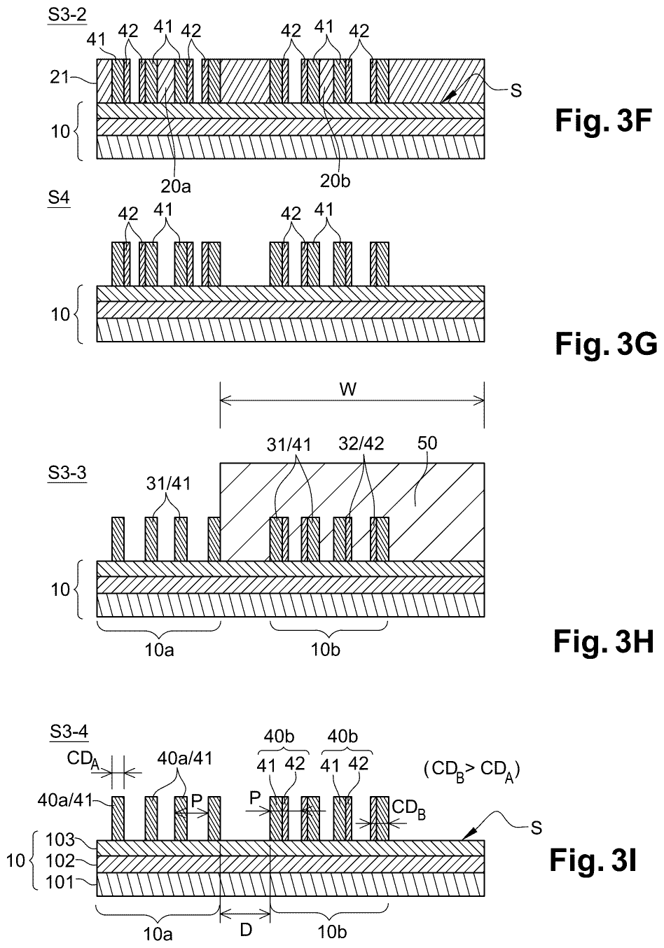

FIGS. 3A-3I, 4A-4I and 5A-5H represent three embodiments of a method for forming patterns on a surface S of a substrate 10. With reference to FIGS. 3I, 4I and 5H, this method makes it possible to obtain a first group of patterns 40a in a first region 10a of the surface S of the substrate 10 and a second group of patterns 40b in a second region 10b of the surface S of the substrate 10. The patterns 40a-40b are patterns projecting from the surface S of the substrate 10. They are, for example in the form of lines, these lines being oriented, in an embodiment, in parallel to each other. The surface S of the substrate 10 may be planar or have a topography (<40 nm).

The substrate 10 may comprise a support layer 101, for example of a semiconductor material such as silicon, a hard mask layer 102 disposed on the support layer 101 and an etching stop layer 103 disposed on the hard mask layer 102. The patterns 40a-40b are then disposed on the etching stop layer 103, which forms the surface S of the substrate 10.

Each of the patterns 40a of the first group is formed by a spacer and each of the patterns 40b of the second group is formed by two spacers adjoining each other. The spacers are projecting patterns formed in pairs on the flanks of other topographical patterns called mandrels or guides.

The patterns 40a of the first group have a critical dimension CD_{A} smaller than the critical dimension CD_{B} of the patterns 40b of the second group. The “critical dimension” is the smallest dimension of the patterns in a plane parallel to the surface S of the substrate 10. Here, the critical dimension of patterns 40a-40b corresponds to their width (measured in the cross-sectional plane of the figures). The critical dimensions CD_{A} and CD_{B} of the patterns 40a-40b are beneficially less than 40 nm. Furthermore, the difference between the critical dimension CD_{B} of the patterns 40b of the second group and the critical dimension CD_{A} of the patterns 40a of the first group is, in an embodiment, greater than or equal to 4 nm, beneficially between 4 nm and 70 nm.

On the other hand, the patterns 40a of the first group and the patterns 40b of the second group have the same pitch P. The pitch P is the distance separating the same edges (or centres) of two consecutive patterns within the same group. The pitch P of the patterns 40a-40b is, in an embodiment, less than 80 nm.

A first embodiment of the formation method will now be described, step by step, with reference to FIGS. 3A-3I.

The formation method firstly comprises a step S1 aimed at forming one or more first sacrificial patterns 20a (or mandrels) in the first region 10a and one or more second sacrificial patterns 20b (or mandrels) in the second region 10b. The first sacrificial patterns 20a have a first critical dimension CD₁ and the second sacrificial patterns 20b have a second critical dimension CD₂ strictly smaller than the first critical dimension CD₁. The difference between the first critical dimension CD₁ and the second critical dimension CD₂ is, in an embodiment, greater than or equal to 4 nm, beneficially between 4 nm and 70 nm.

For the sake of simplicity, the example of a single first sacrificial pattern 20a and a single second sacrificial pattern 20b will be taken hereinafter.

The first step S1 can be splitted into two sub-steps S1-1 and S1-2, illustrated in FIGS. 3A and 3B respectively, themselves comprising several operations.

The first sub-step S1-1 (cf. FIG. 3A) comprises depositing a sacrificial layer 21 onto the surface S of the substrate 10 and forming a first etch mask 22 on the sacrificial layer 21. The material of sacrificial layer 21 is, for example, spin-on carbon (SOC), amorphous carbon (a-C), amorphous silicon (a-Si), a resin, silicon nitride (SiN) or silicon dioxide (SiO₂). The thickness of the sacrificial layer 21 is, in an embodiment, between 50 nm and 100 nm.

Forming the first etch mask 22 comprises an operation of photolithography of a resin layer 221, and beneficially, an operation of transferring the photolithographed patterns into an underlying hard mask layer 222. A 193 nm immersion scanner may be used during the photolithography operation. The hard mask layer 222 is formed, for example, of a Silicon containing Anti-Reflective Coating (SiARC) or a Dielectric Anti-Reflective Coating (DARC). SiARC has the benefit that, like SOC (sacrificial layer 21), it can be deposited by spin-coating, whereas DARC and amorphous carbon are generally deposited by Plasma Enhanced Chemical Vapour Deposition (PECVD).

The second sub-step S1-2 (see FIG. 3B) comprises etching the sacrificial layer 21 through the first etch mask 22 until it reaches the surface S of the substrate 10, and removing the etch mask 22 selectively with respect to the sacrificial layer 21 and the substrate 10. Etching of the sacrificial layer 21, in an embodiment, stops at the etching stop layer 103, for example of titanium nitride (TiN) or silicon.

Thus, the patterns photolithographed in the resin layer 221 are transferred into the sacrificial layer 21 and form the sacrificial patterns 20a-20b. The critical dimensions of the photolithographed patterns (FIG. 3A) can be kept or reduced during transfer, in order to achieve the desired values of critical dimensions for the first sacrificial pattern 20a (CD₁) and for the second sacrificial pattern 20b (CD₂).

The method then comprises a step S2 of forming first spacers 41 in the first region 10a, on the flanks (or side walls) of the first sacrificial pattern 20a, and first spacers 41 in the second region 10b, on the flanks of the second sacrificial pattern 20b.

Forming the first spacers 41 comprises two sub-steps S2-1 and S2-2, illustrated in FIGS. 3C and 3D respectively.

The first sub-step S2-1 (cf. FIG. 3C) consists in conformally depositing a first so-called structural layer 31 in the first and second regions 10a-10b, so as to completely cover the first sacrificial pattern 20a and the second sacrificial pattern 20b (in other words, the flanks and the upper face of the sacrificial patterns 20a-20b). The first layer 31 is termed “structural” because it serves to form at least part of the final patterns 40a-40b, as opposed to a so-called “sacrificial” layer which is destined to completely disappear before the end of the method.

The first structural layer 31 thus has a constant thickness e₁ and embraces the relief formed on the surface S of the substrate 10. The thickness e₁ of the first structural layer 31 is, in an embodiment, between 10 nm and 36 nm, for example equal to 20 nm. The material of the first structural layer 31 may be silicon dioxide (SiO₂) or silicon nitride (SiN).

The first structural layer 31 is, in an embodiment, deposited onto the entire surface S of the substrate 10 (so-called ‘full plate’ deposition). The conformal deposition technique used to form the first structural layer 31 is, for example, Atomic Layer Deposition (ALD), possibly plasma enhanced (Plasma Enhanced Atomic Layer Deposition, PEALD), or Plasma Enhanced Chemical Vapour Deposition (PECVD). The maximum deposition temperature especially depends on the material chosen to form the sacrificial patterns 20a-20b (material of the sacrificial layer 21). For example, some SOCs require a maximum deposition temperature of about 275° C., whereas amorphous carbon (deposited by PECVD) and amorphous silicon (deposited by PECVD or even LPCVD) can withstand higher temperatures.

During the second sub-step S2-2 (see FIG. 3D), the first structural layer 31 is anisotropically etched, in a preferred etching direction perpendicular to the surface S of the substrate 10 (or to the plane in which the substrate extends). This anisotropic etching step makes it possible to remove only the horizontal parts of the first structural layer 31, disposed on the surface S of the substrate 10 and on the upper faces of the sacrificial patterns 20a-20b. The vertical parts of the first structural layer 31, disposed against the flanks of the sacrificial patterns 20a-20b, are kept and constitute the first spacers 41.

The method then comprises a step S3 of forming a second spacer 42 on a flank of each first spacer 41 located in the second region 10b only. This step can be splitted into four sub-steps S3-1 to S3-4 illustrated by FIGS. 3E-3F and 3H-3I.

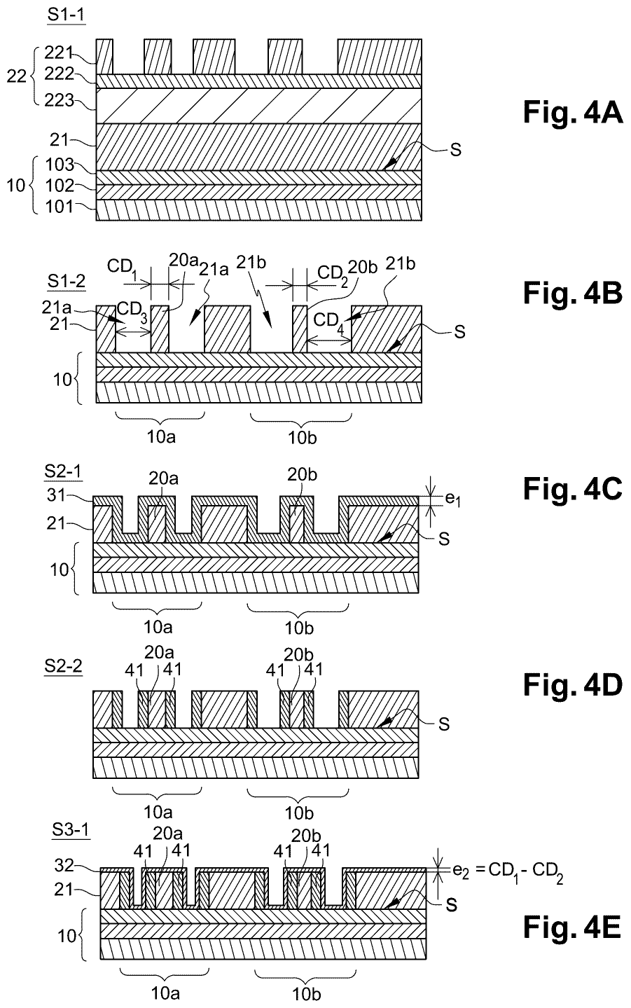

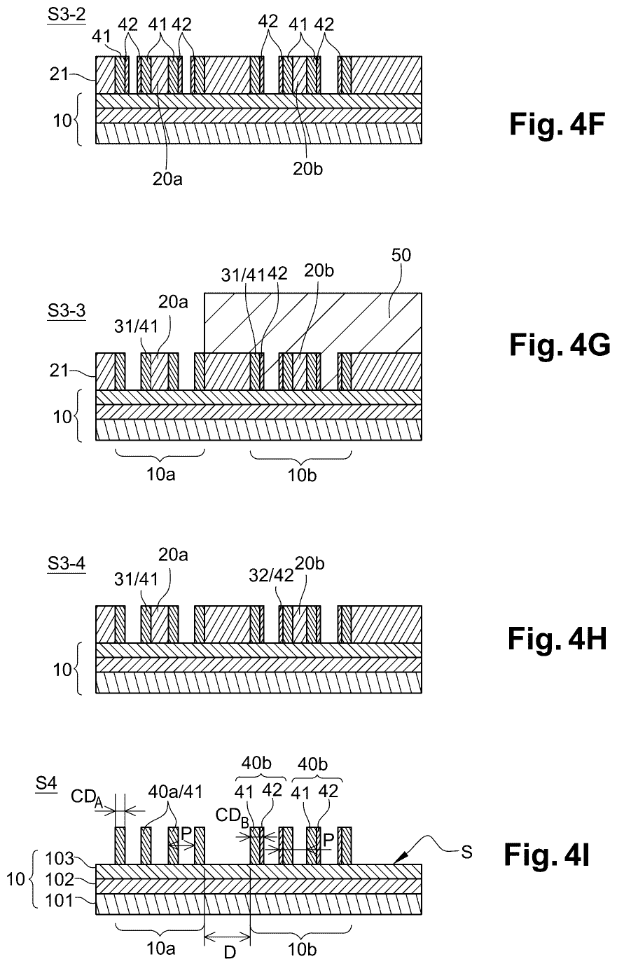

In this first embodiment (as in the second embodiment described hereinafter in connection with FIGS. 4A-4I), the second spacers 42 are first formed in both regions 10a-10b (sub-steps S3-1 and S3-2), then the second spacers 42 located in the first region 10a are removed (sub-steps S3-3 and S3-4), to keep only the second spacers 42 located in the second region 10b.

The second spacers 42 are formed in the same way as the first spacers 41 (described in connection with FIGS. 3C-3D), in two sub-steps S3-1 and S3-2 illustrated by FIG. 3E and FIG. 3F respectively:
S3-1: conformally depositing a second structural layer 32 in the first and second regions 10a-10b (for example by ALD, PEALD or PECVD), here completely covering the sacrificial patterns 20a-20b and the first spacers 41; and then
S3-2: anisotropically etching the second structural layer 32, in a preferential etching direction perpendicular to the surface S of the substrate 10 (or to the plane of the substrate 10).

The thickness e₂ of the second structural layer 32 is constant and equal to the difference between the first critical dimension CD₁ (first sacrificial pattern 20a) and the second critical dimension CD₂ (second sacrificial pattern 20b), i.e.:

$${e}_{2} = C {D}_{1} - C {D}_{2} \qquad [ Math . 1 ]$$

The thickness e₂ of the second structural layer 32 is therefore, in an embodiment, greater than or equal to 4 nm, beneficially between 4 nm and 70 nm.

The material of the second structural layer 32 may be silicon dioxide (SiO₂), silicon nitride (SiN), aluminium oxide (Al₂O₃) or titanium dioxide (TiO₂). It is chosen so that it can be etched selectively with respect to the material of the first structural layer 31 (and with respect to the substrate 10).

In the third sub-step S3-3 represented in FIG. 3H, a second etch mask 50 is formed in the second region 10b (or outside the first region 10a), so as to protect the first and second spacers 41-42 located in this second region 10b. The second spacers 42 in the first region 10a are then etched through the second etch mask 50 selectively with respect to the first spacers 41 (and with respect to the substrate 10).

The second etch mask 50 is for example formed by a two-layer stack comprising a layer of photosensitive resin disposed on a Bottom Anti-Reflective Coating (BARC) (resin/BARC), or even a single layer of resin when dimensions allow (especially the distance between the groups of patterns).

As the first and second regions 10a-10b of the surface S are much larger than the critical dimensions of the patterns 40a-40b to be formed, or even of the sacrificial patterns 20a-20b, the formation of the second etch mask 50 may comprise a conventional photolithography operation, for example using a 193 nm immersion scanner. In other words, this second photolithography operation is relaxed in terms of dimensioning. Typically, the zone covered by the second etch mask 50 may have a width W of between 100 nm and 100 μm, for example equal to 1 μm.

Finally, with reference to FIG. 3I, the second etch mask 50 is removed (selectively with respect to the spacers 41-42 and the substrate 10) in sub-step S3-4.

In other words, sub-steps S3-3 and S3-4 of FIGS. 3H and 3I remove from the first region 10a the second structural layer 32, here structured as the second spacers 42, selectively with respect to the first structural layer 31, itself structured as the first spacers 41.

An isotropic etching method is beneficially used to selectively etch the second structural layer 32 (or the second spacers 42) in the first region 10a. Examples of isotropic etching methods are given hereinafter, depending on the materials of the first and second structural layers 31-32.

Between the sub-step S3-2 of anisotropically etching the second structural layer 32 and the sub-steps S3-3 and S3-4 of removing the second structural layer 32 in the first region 10a, the formation method according to the first embodiment comprises a step S4 of removing the first and second sacrificial patterns 20-20b, selectively with respect to the first and second spacers 41-42 and the substrate 10 (cf. FIG. 3G). Again, an isotropic (and selective) etching method is beneficially used. Byway of example, O₂- or H₂-based plasma etching (N₂/H₂, O₂/N₂, O₂, SO₂/O₂, etc.) can be mentioned in the case of a carbon material (e.g. a-C, SOC), and in the case of amorphous silicon, wet etching (e.g. tetramethylammonium hydroxide (TMAH)) or HBr or Cl₂-based plasma etching (HBr/O₂ or HBr/Cl₂/O₂, NF₃/HBr . . . ).

Thus, at the end of the formation method (see FIG. 3I), the patterns 40a of the first group (in the first region 10a) are formed by the first spacers 41. Their critical dimension CD_{A} is equal to the thickness e₁ of the first structural layer 31.

$$C {D}_{A} = {e}_{1} \qquad [ Math . 2 ]$$

The patterns 40b of the second group (in the second region 10b) are each formed by the juxtaposition of a first spacer 41 and a second spacer 42. Their critical dimension CD_{B} is equal to the sum of the thickness e₁ of the first structural layer 31 and the thickness e₂ of the second structural layer 32.

$$C {D}_{B} = {e}_{1} + {e}_{2} \qquad [ Math . 3 ]$$

The pitch P of the patterns 40a of the first group is equal to the sum of their critical dimension CD_{A} and the critical dimension CD₁ of the first sacrificial pattern 20a, but also to the sum between the thickness e₁ of the first structural layer 31, the thickness e₂ of the second structural layer 32 and the critical dimension CD₂ of the second sacrificial pattern 20b (see relationship [Math. 1]), and therefore to the pitch of the patterns 40b of the second group.

$$P = C {D}_{A} + C {D}_{1} = {e}_{1} + C {D}_{1} = {e}_{1} + {e}_{2} + C {D}_{2} = C {D}_{B} + C {D}_{2} \qquad [ Math . 4 ]$$

There are numerous combinations of materials and techniques (deposition, etching, etc.) for implementing steps S1 to S4 of the method of FIGS. 3A to 3I. According to a first example, the sacrificial layer 21 (forming the sacrificial patterns 20a-20b) is made of a carbon material (e.g. a-C, SOC), the first structural layer 31 (forming the first spacers 41) is of SiO₂ (can be deposited by PEALD), the second structural layer 32 (forming the second spacers 42) is of Al₂O₃ or TiO₂ (can be deposited by ALD) and the etching stop layer 103 of the substrate 10 is made of silicon. The second structural layer 32 is etched (in the first region 10a) isotropically and selectively with respect to the first structural layer 31 (in sub-step S3-3 of FIG. 3H) using a BCl₃/Cl₂ plasma. According to a second example, the sacrificial layer 21 is of a carbon material, the first structural layer 31 is of SiO₂, the second structural layer 32 is of SiN and the etching stop layer 103 of the substrate 10 is of TiN. The second structural layer 32 is etched (in the first region 10a) isotropically and selectively with respect to the first structural layer 31 by means of a fluorine-containing plasma (e.g. SF₆/HBr, NF₃/HBr or CH₃F/O₂/He) without ion bombardment.

FIGS. 4A to 4I represent a second embodiment of the pattern formation method.

This second embodiment differs from the first embodiment in that the step S4 of removing the sacrificial patterns 20a-20b (cf. FIG. 4I) is carried out after the sub-steps S3-3 and S3-4 of removing the second structural layer 32 (structured in the form of the second spacers 42) in the first region 10a (FIG. 4G and FIG. 4H). In other words, the sacrificial patterns 20a-20b are removed at the end of the patterning method.

This timing provides two benefits. Firstly, the sacrificial pattern 20a makes the first spacers 41 more mechanically stable, when etching the second spacers 42 located in the first region 10a (sub-step S3-3 of FIG. 4G), which makes it possible to choose wet etching without the risk of collapse of the first spacers 41 (this risk being related, for example, to capillary forces). Secondly, the formation of the second etch mask 50 is easier, as the space to be filled is smaller in the presence of the second sacrificial pattern 20b.

Furthermore, in this second embodiment, the sacrificial layer 21 (and therefore the sacrificial patterns 20a-20b) is beneficially made of an inorganic material, such as amorphous silicon. Thus, when the second etch mask 50 is formed (sub-step S3-3 of FIG. 4G), the resin/BARC stack (or the resist layer alone) can be removed in the first zone 10a without damaging the first sacrificial pattern 20a.

The first etch mask 22 used to delimit the sacrificial patterns 20a-20b (step S1-1 of FIG. 4A) may in this case include, in addition to the resin layer 221 and the hard mask layer 222 (e.g. SiARC), an SOC layer 223 disposed between the sacrificial layer 21 and the hard mask layer 222.

In the case of a sacrificial layer 21 of amorphous silicon, the etching stop layer 103 of the substrate 10 is, in an embodiment, of TiN.

Beyond these differences, step S1 of forming the sacrificial patterns 20a-20b (FIG. 4A and FIG. 4B), step S2 of forming the first spacers 41 (FIG. 4C and FIG. 4D), step S3 of forming the second spacers 42 in the first region 10a (FIG. 4E, FIG. 4F, FIG. 4G and FIG. 4H) and step S4 of removing the sacrificial patterns 20a-20b (FIG. 4I) are accomplished as described in connection with FIGS. 3A-3I.

There are numerous combinations of materials and techniques (deposition, etching, etc.) for implementing steps S1 to S4 of the method in FIGS. 4A to 4I. According to a first example, the sacrificial layer 21 (forming the sacrificial patterns 20a-20b) is of amorphous silicon, the first structural layer 31 (forming the first spacers 41) is of SiN (resistant to hydrofluoric acid, HF), the second structural layer 32 (forming the second spacers 42) is of SiO₂ (can be deposited by PEALD or ALD at low temperature) and the etching stop layer 103 of the substrate 10 is of TiN. HF-based wet etching is accomplished to remove the second structural layer 32 in the first region 10a (sub-step S3-3 in FIG. 4G). According to a second example, sacrificial layer 21 is of amorphous silicon, first structural layer 31 is of SiO₂, second structural layer 32 is of SiN and etching stop layer 103 of substrate 10 is of TiN. The second structural layer 32 is etched (in the first region 10a) isotropically and selectively with respect to the first structural layer 31 by means of a fluorine-containing plasma (e.g. SF₆/HBr or CH₃F/O₂/He) without ion bombardment.

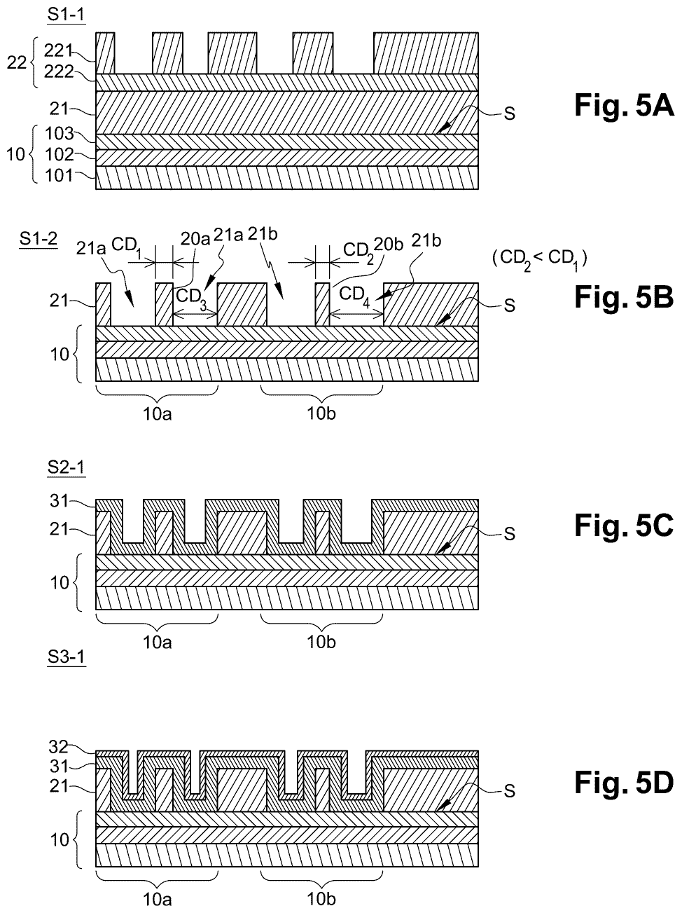

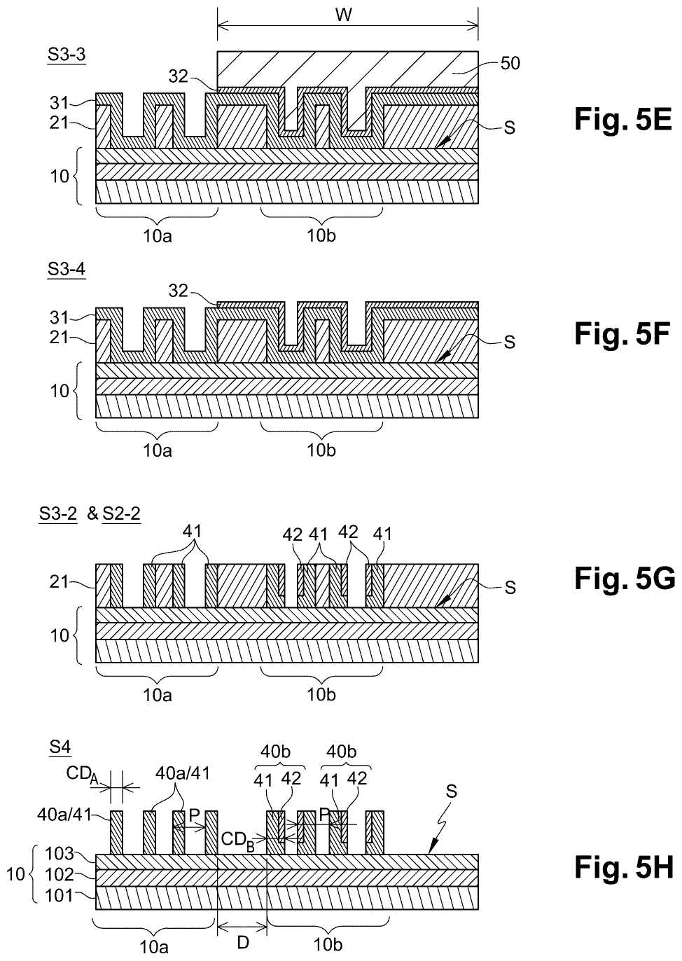

FIGS. 5A to 5H represent a third embodiment of the method for forming patterns, which differs from both previous ones by a different timing in the manufacturing steps and sub-steps.

Thus, in this third embodiment, conformally depositing the second structural layer 32 (sub-step S3-1 represented by FIG. 5D) is subsequent to conformally depositing the first structural layer 31 (sub-step S2-1 represented by FIG. 5C) and anisotropically etching the first structural layer 31 (sub-step S2-2) is subsequent to anisotropically etching the second structural layer 32 (sub-step S3-2, cf. FIG. 5G).

In other words, both structural layers 31-32 are deposited on top of each other, beneficially using the same etching technique (PEALD, ALD and PECVD) (FIG. 5D), and then etched after each other to delimit the first and second spacers 41-42, for example using a same etching method, for example fluorine-based plasma etching (e.g. CH₂F₂/He/CF₄ or CF₄/Ar) with ion bombardment (FIG. 5G).

Besides, sub-steps S3-3 and S3-4 of step S3 (see FIG. 5E and FIG. 5F), for removing the second structural layer 32 in the first region 10a, are accomplished prior to anisotropic etching of the second structural layer 32 (FIG. 5G). In other words, the etch mask 50 is formed on the first and second structural layers 31-32 before they are structured in the form of the first spacers 41 and second spacers 42 respectively. Similarly, the second structural layer 32 is removed in the first zone 10a, selectively with respect to the first structural layer 31, before it is structured as the second spacers 42.

Removing the sacrificial patterns 20a-20b (step S4 of FIG. 5H) is accomplished after the anisotropic etching sub-steps S3-2 and S2-2, thus after removing the second structural layer 32 in the first region 10a (sub-steps S3-3 and S3-4 of FIGS. 5E-5F), as in the second embodiment.

This third embodiment is the simplest to implement, as both conformal deposition steps are consecutive and both anisotropic etching steps are also consecutive. On the other hand, there is a risk of worse control of critical dimension of the spacers, as the thickness of the layers to be anisotropically etched varies between both regions 10a-10b. More precisely, in the first region 10a, the horizontal portions of the first structural layer, having thickness e₁, are removed, whereas in the second region 10b, the horizontal portions of the first structural layer 31 and the second structural layer 32, i.e. the combined thicknesses e₁ and e₂, are removed.

Step S1 of forming the sacrificial patterns 20a-20b (FIG. 5A and FIG. 5B) can be accomplished as described in connection with FIGS. 3A-3B.

There are many combinations of materials and techniques (deposition, etching . . . ) to implement steps S1 to S4 of the method of FIGS. 5A to 5H. According to a first example, the sacrificial layer 21 is of a carbon material or amorphous silicon, the first structural layer 31 is of SiO₂, the second structural layer 32 is of SiN (can be deposited by PEALD or ALD) and the etching stop layer 103 of the substrate 10 is made of TiN. Etching using a fluorine-containing plasma (e.g. SF₆/HBr or CH₃F/O₂/He) without ion bombardment is accomplished to remove the second structural layer 32 in the first region 10a (sub-step S3-3 in FIG. 5E). According to a second example, the sacrificial layer 21 is of a carbon material or amorphous silicon, the first structural layer 31 is of SiN (resistant to hydrofluoric acid, HF), the second structural layer 32 is of SiO₂ (can be deposited by PEALD or ALD at low temperature) and the etching stop layer 103 of the substrate 10 is of TiN. HF-based wet etching is accomplished to remove the second structural layer 32 in the first region 10a.

The method described above in connection with FIGS. 3A-3I, 4A-4I and 5A-5H makes it easy to obtain patterns 40a-40b with a small critical dimension difference, typically greater than or equal to 4 nm, because this critical dimension difference corresponds to the thickness of a conformal deposition, a manufacturing step that is well mastered in the microelectronics industry. Furthermore, patterns obtained are symmetrical in terms of pitch and critical dimension, unlike those obtained with the method of prior art (FIG. 2; SADP region).

The patterns 40a-40b formed on the surface S of the substrate 10 can then be transferred into the substrate 10, to form an integrated circuit level, for example transistor gates or interconnection lines. In the integration example described above, the patterns 40a-40b are first transferred into the etching stop layer 103, then into the hard mask layer 102, and finally into the support layer 101.

The two groups of patterns are beneficially spaced apart by a distance D greater than or equal to the first critical dimension CD₁, in an embodiment, between 44 nm and 10 μm, for example equal to 300 nm.

As is illustrated in the figures, the first sacrificial pattern 20a can separate two first cavities 21a having a third critical dimension CD₃ and the second sacrificial pattern 20b can separate two second cavities 21b having a fourth critical dimension CD₄.

These cavities 21a-21b are formed by etching the sacrificial layer 21 during the second sub-step S1-2 of the step S1 of forming the sacrificial patterns 20A-20b.

They make it possible to form two other first spacers 41 and two other second spacers 42 in each region 10a, 10b of the surface S of the substrate 10, on side walls of the cavities 21a-21b located opposite the flanks of the sacrificial patterns 20a, 20b, and thus to increase (from 2 to 4) the number of patterns 40a, 40b in each group. The flanks of the sacrificial patterns 20a, 20b also constitute side walls of the cavities 21a-21b.

For this, the conformal deposition of the first structural layer 31 is accomplished so that it covers the bottom and side walls of the cavities 21a-21b (but does not completely fill them) and the conformal deposition of the second structural layer 32 is accomplished so that it covers the bottom and side walls of the cavities 21a-21b (but does not completely fill them).

For the pitch P of the patterns 40a, 40b to be constant, the third critical dimension CD₃ and the fourth critical dimension CD₄ satisfy the following relationships:

$$C {D}_{3} = C {D}_{1} + 2 \times {e}_{1} \qquad [ Math . 5 ]$$

where CD₁ is the first critical dimension (first sacrificial pattern 20a) and e₁ is the thickness of first structural layer 31; and

$$C {D}_{4} = C {D}_{2} + 2 \times {e}_{1} + 2 \times {e}_{2} \qquad [ Math . 6 ]$$

where CD₂ is the second critical dimension (second sacrificial pattern 20b), e₁ is the thickness of first structural layer 31 and e₂ is the thickness of second structural layer 32.

Each region 10a, 10b can contain several sacrificial patterns 20a, 20b of the same critical dimension CD₁, CD₂ (and separated two by two by a cavity 21a, 21b) in order to obtain a number of patterns greater than 4 in the corresponding group.

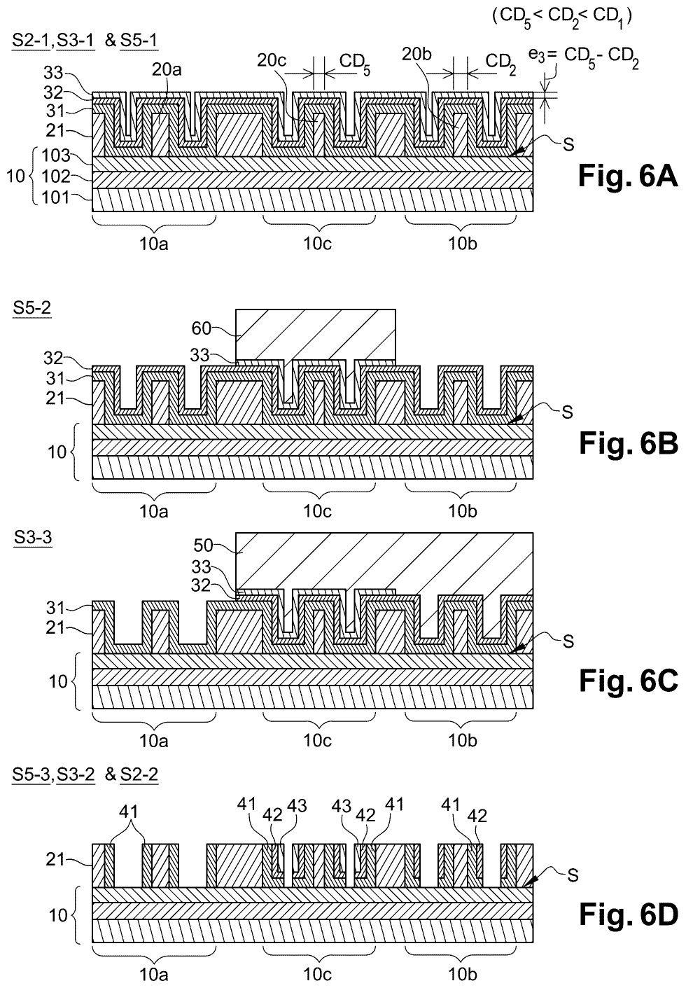

The pattern formation method can be extended to more than two groups of patterns. FIGS. 6A to 6D represent an embodiment of the method for forming three groups of patterns (of different critical dimensions but having a same pitch).

At least a third sacrificial pattern 20c is formed in a third region 10c of the substrate 10, in an embodiment, at the same time as the first and second sacrificial patterns 20a-20b (and in the manner described above). This third sacrificial pattern 20c has a critical dimension CD₅ strictly smaller than the (second) critical dimension CD₂ of the second sacrificial pattern 20b. The difference between the critical dimension CD₅ of the third sacrificial pattern 20c and the critical dimension CD₂ of the second sacrificial pattern 20b is, in an embodiment, greater than or equal to 4 nm, beneficially between 4 nm and 70 nm.

In addition to the steps S1-S4 described previously, the formation method comprises a step S5 of forming a third spacer 43 on a flank of each second spacer 42 located in the third region 10c, whereby each pattern of the third region 10c is formed by the juxtaposition of a first spacer 41, a second spacer 42 and a third spacer 43.

Forming the third spacers 43 comprises the sub-steps of:
S5-1: conformally depositing a third structural layer 33 in the first, second and third regions 10a-10c, the third structural layer 43 having a thickness e₃ equal to the difference between the second critical dimension CD₂ of the second sacrificial pattern 20b and the critical dimension CD₅ of the third sacrificial pattern 20c (cf. FIG. 6A);
S5-2: removing the third structural layer 33 in the first and second regions 10a-10b (see FIG. 6B); and
S5-3: anisotropically etching the third structural layer 33 (in a preferred direction perpendicular to the substrate surface S) (see FIG. 6D).

Conformally depositing the third structural layer 33 (sub-step S5-1; see FIG. 6A) may be subsequent to conformally depositing the second structural layer 32 (sub-step S3-1), itself subsequent to conformally depositing the first structural layer 31 (sub-step S2-1), so that the third structural layer 33 is deposited onto the first and second structural layers 31-32 prior to their etching as spacers.

Removing the third structural layer 33 in a localised manner, in an embodiment, comprises:
forming a third etch mask 60 (e.g. resin/BARC) in the third region 10c (or outside the first and second regions 10a-10b), so as to protect the portions of the first, second and third structural layers 31-33 located in this third region 10c;
etching the third structural layer 33 through the third etch mask 60 selectively with respect to the second structural layer 32 and, in an embodiment, isotropically; and
removing the third etch mask 60 (selectively with respect to the second structural layer 32 and the third structural layer 33).

In addition to the second region 10b, the second etch mask 50 covers the third region 10c, so as to retain the second structural layer 32 also in the third region 10c upon removing the second structural layer 32 from the first region 10a (sub-step S3-3 of FIG. 6C).

The anisotropic etching operations of the third structural layer 33 (sub-step S5-3), the second structural layer 32 (sub-step S3-2) and the first structural layer 31 (sub-step S2-2) may follow one another in this order (see FIG. 6D). They are, in an embodiment, accomplished using a same etching method.

In one alternative embodiment, the third structural layer 33 is conformally deposited (sub-step S5-1) and removed from the first and second regions 10a-10b (sub-step S5-2) before the second structural layer 32 is deposited (sub-step S3-1) and removed from the first region 10a (sub-steps S3-3 and S3-4).

Numerous alternatives and modifications to the pattern formation method will become apparent to the person skilled in the art. Patterns formed can adopt geometries other than parallel lines. The patterns can especially be rings (or hollowed out cylinders) or lines perpendicular to each other.

The articles “a” and “an” may be employed in connection with various elements, components, processes or structures described herein. This is merely for convenience and to give a general sense of the elements, components, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The present invention has been described and illustrated in the present detailed description and in the figures of the appended drawings, in possible embodiments. The present invention is not however limited to the embodiments described. Other alternatives and embodiments may be deduced and implemented by those skilled in the art on reading the present description and the appended drawings.

In the claims, the term “includes” or “comprises” does not exclude other elements or other steps. The different characteristics described and/or claimed may be beneficially combined. Their presence in the description or in the different dependent claims do not exclude this possibility. The reference signs cannot be understood as limiting the scope of the invention.

1. A method for forming a first group of patterns and a second group of patterns on a surface of a substrate, the first group of patterns being located in a first region of the surface of the substrate and the second group of patterns being located in a second region of the surface of the substrate, the method comprising:
forming a first sacrificial pattern and a second sacrificial pattern on the substrate, the first sacrificial pattern being located in the first region and having a first critical dimension, the second sacrificial pattern being located in the second region and having a second critical dimension strictly smaller than the first critical dimension;
forming first spacers in the first region, on flanks of the first sacrificial pattern, and in the second region, on flanks of the second sacrificial pattern, forming the first spacers comprising the following sub-steps of:
conformally depositing a first structural layer in the first and second regions;
anisotropically etching the first structural layer;
forming a second spacer on a flank of each first spacer located in the second region, forming the second spacers comprising the following sub-steps of:
conformally depositing a second structural layer in the first and second regions, the second structural layer having a thickness equal to a difference between the first critical dimension and the second critical dimension;
anisotropically etching the second structural layer; and
removing the second structural layer in the first region;
removing the first and second sacrificial patterns selectively with respect to the first and second spacers.

2. The method according to claim 1, wherein:
the first sacrificial pattern separates two first cavities having a third critical dimension;
the second sacrificial pattern separates two second cavities having a fourth critical dimension; and
the first and second spacers are formed on side walls of the first and second cavities.

3. The method according to claim 2, wherein the third critical dimension and the fourth critical dimension satisfy the following relationships:
$${CD}_{3} = C {D}_{1} + 2 \times {e}_{1}$$
$${CD}_{4} = C {D}_{2} + 2 \times {e}_{1} + 2 \times {e}_{2}$$
where CD₁ is the first critical dimension, e₁ is the thickness of the first structural layer, CD₂ is the second critical dimension and e₂ is the thickness of the second structural layer.

4. The method according to claim 1, wherein conformally depositing the second structural layer is accomplished after anisotropically etching the first structural layer.

5. The method according to claim 1, wherein conformally depositing the second structural layer is subsequent to conformally depositing the first structural layer and wherein anisotropically etching the first structural layer is subsequent to anisotropically etching the second structural layer.

6. The method according to claim 1, wherein removing the second structural layer) in the first region is accomplished after anisotropically etching the second structural layer.

7. The method according to claim 1, wherein removing the second structural layer in the first region is accomplished prior to anisotropically etching the second structural layer.

8. The method according to claim 1, wherein removing the first and second sacrificial patterns is accomplished after removing the second structural layer in the first region.

9. The method according to claim 1, wherein etching the first and second sacrificial patterns is accomplished between anisotropically etching the second structural layer and etching the second structural layer in the first region.

10. The method according to claim 1, wherein removing the second structural layer in the first region comprises forming an etch mask on the second structural layer in the second region, etching the second structural layer through the etch mask selectively with respect to the first sacrificial layer, and removing the etch mask.

11. The method according to claim 1, wherein the difference between the first critical dimension and the second critical dimension is greater than or equal to 4 nm.

12. The method according to claim 11, wherein the difference between the first critical dimension and the second critical dimension is between 4 nm and 70 nm.
